(19) United States
(12) Patent Application Publication
(10) Pub. No.: US 2024/0171152 A1
(43) Pub. Date: May 23, 2024

(54) ACOUSTIC WAVE DEVICE

(71) Applicant: Murata Manufacturing Co., Ltd., Nagaokakyo-shi (JP)

(72) Inventors: Hideki IWAMOTO, Nagaokakyo-shi (JP); Akira MICHIGAMI, Nagaokakyo-shi (JP); Hiromu OKUNAGA, Nagaokakyo-shi (JP)

(21) Appl. No.: 18/420,931

(22) Filed: Jan. 24, 2024

Related U.S. Application Data
(63) Continuation of application No. PCT/JP2022/035464, filed on Sep. 22, 2022.

(30) Foreign Application Priority Data
Sep. 27, 2021 (JP) 2021-156961

(51) Int. Cl. H03H 9/145; H03H 9/02; H03H 9/25

(52) U.S. Cl. CPC H03H 9/145; H03H 9/02559; H03H 9/02574; H03H 9/02637; H03H 9/25

(57) ABSTRACT

An acoustic wave device includes an Interdigital Transducer (IDT) electrode on a first main surface of a piezoelectric layer, a conductive material layer on a second main surface of the piezoelectric layer, and a dielectric layer provided between the piezoelectric layer and the conductive material layer. When a film thickness of the piezoelectric layer is represented as Tp[λ] and a film thickness of the dielectric layer is represented as Td[λ], the Formula (1) is satisfied or Td=0, where λ is a wavelength determined by an electrode finger pitch of the IDT electrode, and Tp[λ]≥about 0.025:

Td[λ]≤−2.369×(Tp[λ])⁴

+2.721×(Tp[λ])³

−1.049×(Tp[λ])²

+0.076×(Tp[λ])

+0.095 Formula (1).

### CROSS REFERENCE TO RELATED APPLICATIONS

This application claims the benefit of priority to Japanese Patent Application No. 2021-156961, filed on Sep. 27, 2021, and is a Continuation Application of PCT Application No. PCT/JP2022/035464, filed on Sep. 22, 2022. The entire contents of each application are hereby incorporated herein by reference.

### BACKGROUND OF THE INVENTION

### 1. Field of the Invention

The present invention relates to acoustic wave devices in each of which a conductive material layer is provided below a piezoelectric layer.

### 2. Description of the Related Art

US 2017/0288629A1 discloses an acoustic wave device having a low-resistance layer made of metal or other materials. In the acoustic wave device described in US 2017/0288629A1, a low-resistance layer is provided on a support substrate, and a piezoelectric layer and an IDT electrode are stacked on the low-resistance layer.

In US 2017/0288629A1, the above low-resistance layer is provided for suppressing spurious responses.

Acoustic wave devices such as those described in US 2017/0288629A1 are used, for example, in bandpass filters. In recent years, this type of acoustic wave device is required to be able to efficiently adjust the fractional bandwidth in order to obtain the steepness of the filter characteristics in the bandpass filter. However, it is difficult to adjust the fractional bandwidth in the acoustic wave device described in US 2017/0288629A1.

### SUMMARY OF THE INVENTION

Example embodiments of the present invention provide acoustic wave devices each able to reduce the fractional bandwidth. An example embodiment of an acoustic wave device according to the present invention includes a piezoelectric layer including a first main surface and a second main surface opposing each other, an Interdigital Transducer (IDT) electrode on the first main surface of the piezoelectric layer, a dielectric layer on the second main surface of the piezoelectric layer, and a conductive material layer on a surface of the dielectric layer on a side opposite to the piezoelectric layer. The conductive material layer is provided in at least a portion of a region overlapping the IDT electrode in a plan view. When a film thickness of the piezoelectric layer is represented as Tp [λ] and a film thickness of the dielectric layer is represented as Td [λ], the following Formula (1) is satisfied or Td=0, where λ is a wavelength determined by an electrode finger pitch of the IDT electrode, and Tp[λ]≥0.025.

Td[λ]≤−2.369×(Tp[λ])⁴

+2.721×(Tp[λ])³

−1.049×(Tp[λ])²

+0.076×(Tp[λ])

+0.095 Formula (1)

An example embodiment of an acoustic wave device according to the present invention includes a piezoelectric layer including a first main surface and a second main surface opposing each other, an Interdigital Transducer (IDT) electrode on the first main surface of the piezoelectric layer, and a conductive material layer on a side of the second main surface of the piezoelectric layer. The IDT electrode includes a first busbar and a second busbar, a plurality of first electrode fingers electrically connected to the first busbar, and a plurality of second electrode fingers electrically connected to the second busbar. When an area of the conductive material layer in a first overlapping region that overlaps at least a portion of the first busbar in a plan view is represented as an area S1, when an area of the conductive material layer in a second overlapping region that overlaps at least a portion of the second busbar in the plan view is represented as an area S2, and when the first overlapping region and the second overlapping region of the conductive material layer are electrically connected, and a wavelength determined by an electrode finger pitch of the IDT electrode is represented as X, a total area S, which represents a sum of the area S1 and the area S2, is equal to or less than λ×10⁴ μm².

According to example embodiments of acoustic wave devices of the present invention, the fractional bandwidth is able to be adjusted efficiently.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view illustrating an electrode structure of an acoustic wave device according to a first example embodiment of the present invention.

FIG. 2 is a front cross-sectional view illustrating a main portion of the acoustic wave device according to the first example embodiment of the present invention.

FIG. 3 is a graph showing the relationship between the thickness of a piezoelectric layer Tp [λ], the thickness of a dielectric layer Td [λ], and the fractional bandwidth in Example 1.

FIG. 4 is a schematic plan view explaining the positional relationship between an IDT electrode and a conductive material layer below the IDT electrode in an acoustic wave device according to a second example embodiment of the present invention.

FIG. 5 is a graph showing the relationship between an overlap area S and the fractional bandwidth in Example 2.

FIG. 6 is a schematic plan view explaining the positional relationship between an IDT electrode and a conductive material layer below the IDT electrode in an acoustic wave device according to a variation of the second example embodiment of the present invention.

FIG. 7 is a graph showing the relationship between the film thickness [nm] of Al and the Q characteristics of the acoustic wave device of the second example embodiment of the present invention.

FIG. 8 is a schematic plan view explaining the positional relationship between an IDT electrode and a conductive material layer below the IDT electrode in an acoustic wave device according to a variation of the first example embodiment of the present invention.

FIG. 9 is a schematic plan view explaining the positional relationship between an IDT electrode and a conductive material layer in an acoustic wave device according to a third example embodiment of the present invention.

FIG. 10 is a schematic plan view explaining the positional relationship between an IDT electrode and a conductive material layer in an acoustic wave device according to a fourth example embodiment of the present invention.

FIG. 11 is a graph showing the relationship between the film thickness [μm] of the piezoelectric layer and the TCF [ppm/° C.].

FIG. 12 is a graph showing the relationship between the film thickness [μm] of the piezoelectric layer and the TCF [ppm/° C.].

FIG. 13 is a graph showing the relationship between the film thickness [μm] of the piezoelectric layer and the TCF [ppm/° C.].

### DETAILED DESCRIPTION OF THE EXAMPLE EMBODIMENTS

The present invention will be clarified below by describing example embodiments of the present invention with reference to the drawings.

Each example embodiment described herein is exemplary, and partial substitution or combination of configurations between different example embodiments is possible.

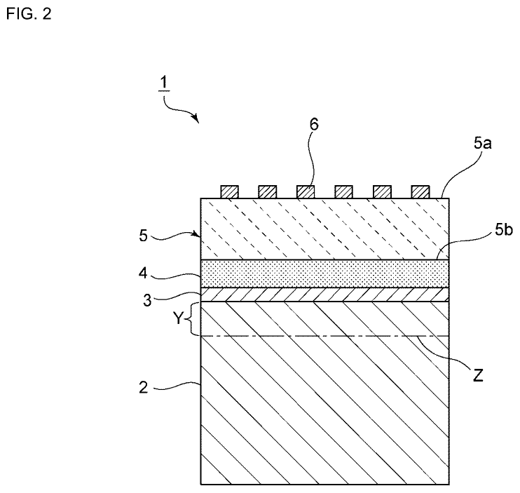

FIG. 2 is a front cross-sectional view illustrating a main portion of an acoustic wave device according to a first example embodiment of the present invention.

An acoustic wave device 1 includes a support substrate 2. In the present example embodiment, the support substrate 2 is preferably made of silicon, for example. However, the material of the support substrate 2 is not particularly limited. A suitable insulator or semiconductor can be used as the material of the support substrate 2. The fractional bandwidth can be adjusted even in a structure without the support substrate 2.

A conductive material layer 3 is provided on the support substrate 2. In the present example embodiment, the conductive material layer 3 is made of Al, for example. However, the conductive material layer 3 may also be made of a suitable metal other than Al, or an alloy, or a semiconductor.

A dielectric layer 4 is provided on the conductive material layer 3. In the present example embodiment, the dielectric layer 4 is made of silicon oxide, for example. However, the dielectric layer 4 may also be made of a dielectric other than silicon oxide.

A dielectric layer Y may be provided on a portion indicated by a dash-dotted line Z in FIG. 2. In other words, the dielectric layer Y may be further provided between the support substrate 2 and the conductive material layer 3.

A piezoelectric layer 5 is provided on the dielectric layer 4. The piezoelectric layer 5 includes a first and a second main surfaces 5a and 5b opposing each other. The second main surface 5b is stacked on the dielectric layer 4. In the present example embodiment, the piezoelectric layer 5 is made of LiNbO₃, for example. However, the piezoelectric layer 5 may also be made of other piezoelectric single crystals such as LiTaO₃, for example. The dielectric layer 4 is not necessarily provided.

An IDT electrode 6 is provided on the first main surface 5a of the piezoelectric layer 5. In the present example embodiment, the IDT electrode 6 is preferably made of Al, for example. However, the material of the IDT electrode 6 may also be made of a metal other than Al or an alloy. Furthermore, the IDT electrode 6 may also be made of a multilayer body including a plurality of metal layers. A protective film may be provided to cover the IDT electrode 6. The protective film is preferably made of, for example, silicon oxide or silicon nitride and has a thickness of, for example, about 10 nm to about 100 nm.

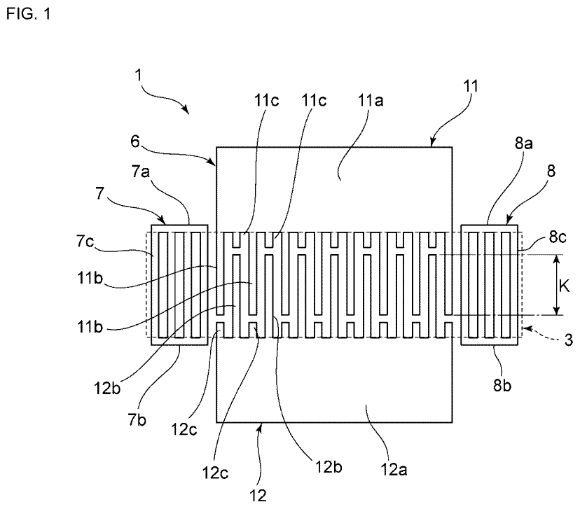

In FIG. 2, only a region where the IDT electrode 6 is provided is shown. However, the acoustic wave device 1 includes first and second reflectors 7 and 8 on both sides of the IDT electrode 6 in the propagation direction of the acoustic wave as shown in FIG. 1. The above components define an acoustic wave resonator.

The IDT electrode 6 includes a first comb-shaped electrode 11 and a second comb-shaped electrode 12. The first comb-shaped electrode 11 includes a first busbar 11a, a plurality of first electrode fingers 11b connected to the first busbar 11a, and a plurality of first dummy electrodes 11c connected to the first busbar 11a.

The second comb-shaped electrode 12 includes a second busbar 12a, a plurality of second electrode fingers 12b connected to the second busbar 12a, and a plurality of second dummy electrodes 12c connected to the second busbar 12a.

The first electrode finger 11b and the first dummy electrode 11c extend from the first busbar 11a toward the second busbar 12a. Similarly, the second electrode finger 12b and the second dummy electrode 12c extend from the second busbar 12a toward the first busbar 11a.

The tip end of the first electrode finger 11b and the tip end of the second dummy electrode 12c face each other with a gap between them. Similarly, the tip end of the first dummy electrode 11c and the tip end of the second electrode finger 12b face each other with a gap between them. The plurality of first electrode fingers 11b and the plurality of second electrode fingers 12b are interdigitated with each other. Here, the distance between the centers of adjacent electrode fingers is called an electrode finger pitch. More specifically, the electrode finger pitch is the center-to-center distance between adjacent electrode fingers connected to different potentials.

When viewed in the propagation direction of the acoustic wave, the region where the first electrode fingers 11b and the second electrode fingers 12b overlap is an intersecting region K.

The propagation direction of the acoustic wave is a direction perpendicular or substantially perpendicular to the direction in which the first and second electrode fingers 11b and 12b extend.

The first reflector 7 includes a first busbar and a second busbar 7a and 7b. One end of a plurality of electrode fingers 7c is connected to the first busbar 7a and the other end is connected to the second busbar 7b.

The second reflector 8 is preferably configured in the same or similar manner as the first reflector 7. In other words, both ends of a plurality of electrode fingers 8c are shorted by a first and a second busbars 8a and 8b. In FIG. 1, both the first and second reflectors 7 and 8 are not connected to the IDT electrode 6. In other words, they are floating electrodes. Thus, the fractional bandwidth can be further adjusted. However, the first and second reflectors 7 and 8 may also be connected to the IDT electrode 6. In this case, spurious responses, which are unwanted waves, are less likely to occur.

The conductive material layer 3 shown in FIG. 2 is not present below all regions where the IDT electrode 6 and the first and second reflectors 7 and 8 are provided. As shown in FIG. 1, in the first example embodiment, the conductive material layer 3 is located below a portion where the above-described first and second electrode fingers 11b and 12b and first and second dummy electrodes 11c and 12c are provided and a region where the electrode fingers 7c and 8c are provided. In other words, the conductive material layer 3 is not located below the first and second busbars 11a and 12a. In this case, the leakage of the acoustic wave in the transverse direction may be reduced or prevented.

In the acoustic wave device 1, the thickness of the dielectric layer 4 is represented as Td [λ] and the thickness of the piezoelectric layer 5 is represented as Tp [λ], where Tp [λ]≥about 0.025, for example. Here, λ is a wavelength determined by the electrode finger pitch of the IDT electrode 6, and specifically, the wavelength λ satisfies λ=2p when the electrode finger pitch is represented as p. Tp [λ] refers to the thickness of the dielectric layer 4 normalized by the wavelength λ, hereafter, all thicknesses denoted by T_[λ] represent values normalized by the wavelength λ.

In the above configuration of the acoustic wave device 1, the thickness Td [λ] of the dielectric layer 4 satisfies the following Formula (1), or Td=0. Thus, the fractional bandwidth can be reduced.

Td[λ]≤−2.369×(Tp[λ])⁴

+2.721×(Tp[λ])³

−1.049×(Tp[λ])²

+0.076×(Tp[λ])

+0.095 Formula (1)

The above is explained in more detail below.

An acoustic wave device with the following configuration was prepared as Example 1 of the acoustic wave device 1.

Support substrate 2: a support substrate made of silicon.

Conductive material layer 3: a film of Al with a thickness of about 50 nm.

Dielectric layer 4: a film of SiO₂ with a thickness varying from about 0λ to about 0.2λ.

Piezoelectric layer 5: a film of LiNbO₃ with a thickness varying from about 0.025λ to about 0.8λ.

IDT electrode 6: a film of Al with a thickness of about 300 nm.

Number of pairs of electrode fingers of IDT electrode 6: 100 pairs, with intersecting width=20λ and duty=about 0.5.

λ=about 5.0 μm.

The conductive material layer is not connected to either the IDT electrode or the reflectors. In other words, the conductive material layer is a floating electrode.

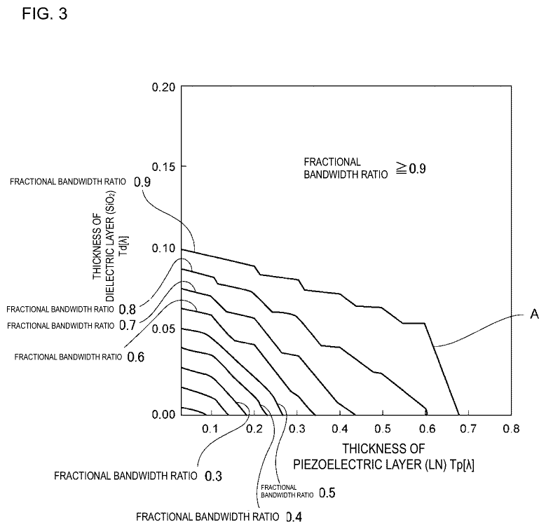

In the acoustic wave device 1 of Example 1, the resonance characteristics were measured and the fractional bandwidth was obtained. The relationship between Tp [λ], Td [λ], and the fractional bandwidth ratio in Example 1 is shown in FIG. 3. The fractional bandwidth ratio in FIG. 3 is BW1/BW0. The fractional bandwidth when the conductive material layer 3 is not provided is BW0, and the fractional bandwidth in Example 1 in which the conductive material layer 3 is provided is BW1. Therefore, BW1/BW0 is the fractional bandwidth ratio. The smaller the fractional bandwidth ratio, the more the fractional bandwidth can be reduced, i.e., the more efficiently the fractional bandwidth can be adjusted.

It can be known that the fractional bandwidth ratio can be equal to or less than about 0.9 in a region where Tp [λ] and/or Td [λ] is thinner than the solid line A in FIG. 3. The reason why the fractional bandwidth can be reduced more in the region where the Tp and Td are thin is believed to be due to the capacitive coupling between the IDT electrode 6 and the conductive material layer 3, with the capacitance connected in parallel to the resonator. It is believed that the thinner the Tp and Td, the greater the capacitance, and therefore the more the fractional bandwidth is reduced.

The region where Tp and Td are thinner than the solid line A in FIG. 3 can be expressed by the following Formula (1).

Td[λ]≤−2.369×(Tp[λ])⁴

+2.721×(Tp[λ])³

−1.049×(Tp[λ])²

+0.076×(Tp[λ])

+0.095 Formula (1)

In Example 1, Td=0 may also be satisfied. In other words, the dielectric layer 4 is not necessarily provided.

The thickness Tp [λ] of the piezoelectric layer 5 is, for example, equal to or greater than about 0.025λ, as described above. If the piezoelectric layer becomes too thin, it may be difficult to efficiently excite the SH wave, which is the main mode. Note that the main mode is not limited to the SH wave.

As described above, according to the present example embodiment, the IDT electrode and the conductive material layer can be capacitively coupled while, on the other hand, the capacitive coupling does not become too strong. Thus, both efficient adjustment of the fractional bandwidth and efficient excitation of the desired mode can be achieved.

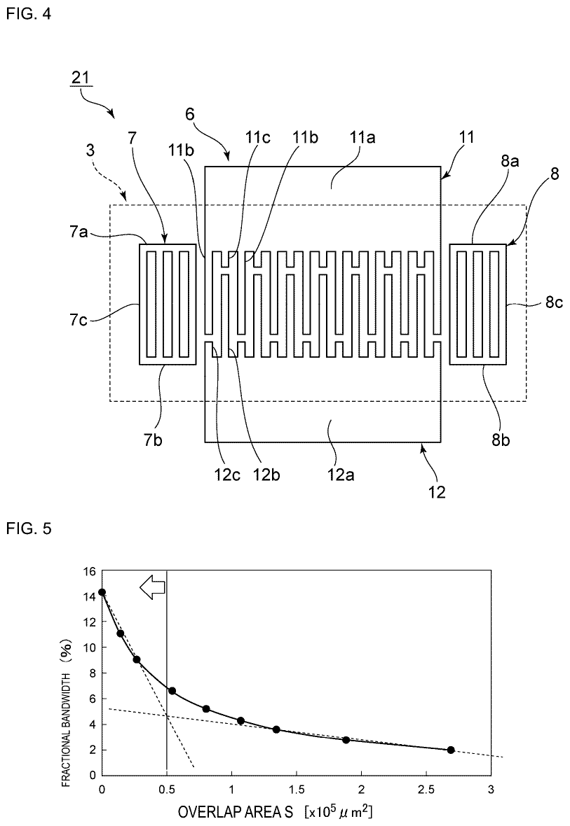

FIG. 4 is a schematic plan view explaining the positional relationship between an IDT electrode and a conductive material layer below the IDT electrode in an acoustic wave device according to a second example embodiment of the present invention.

As shown in FIG. 4, in an acoustic wave device 21, an IDT electrode 6 and a first and a second reflectors 7 and 8 are preferably the same as in the acoustic wave device 1 of the first example embodiment. The acoustic wave device 21 preferably differs in that a conductive material layer 3 located below the IDT electrode 6 further extends below a portion of a first busbar 11a and a second busbar 12a. In the acoustic wave device 21, the conductive material layer 3 may be provided to reach below the first and second busbars 11a and 12a. The conductive material layer 3 may be provided to reach below the entire area of the first and second busbars 11a and 12a.

In the acoustic wave device 21, the conductive material layer 3 overlaps a portion of the first and second busbars 11a and 12a via a piezoelectric layer 5. When a dielectric layer 4 is provided, the portion of the first and second busbars 11a and 12a and the conductive material layer 3 overlap via the dielectric layer 4. Therefore, a capacitance is also generated between the first and second busbars 11a and 12a and the conductive material layer 3.

Even in the acoustic wave device 21 of the second example embodiment, the fractional bandwidth can be reduced due to the capacitance between the conductive material layer 3 and the IDT electrode 6.

In the acoustic wave device 21, the capacitance also varies with the facing area between the first and second busbars 11a and 12a and the conductive material layer 3. The facing area between the first busbar 11a and the conductive material layer 3 is represented as S1, and the facing area between the second busbar 12a and the conductive material layer 3 is represented as S2. S1+S2 is represented as an overlap area S.

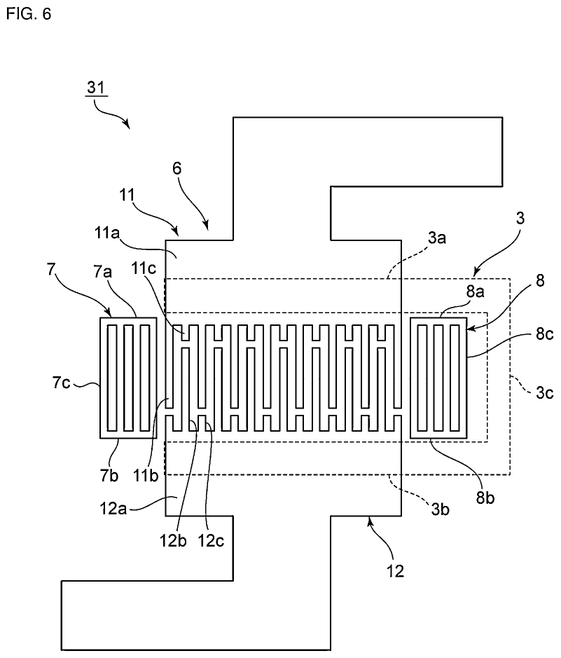

Example 2 was prepared for the acoustic wave device 21, in which the parameters are set the same as in Example 1, except that the number of pairs of the electrode fingers of the IDT electrode 6 was set to 300 pairs and the intersecting width was set to about 30λ. FIG. 5 is a graph showing the relationship between the overlap area S (×10⁵ μm²) and the fractional bandwidth (%) in Example 2. As shown in FIG. 5, the inflection point is at a point where the overlap area S is equal to about 0.5×10⁵ μm².

It is clear from FIG. 5 that as the overlap area S increases, the fractional bandwidth decreases. On the other hand, it is known that when the overlap area S is equal to or less than about 0.5×10⁵ μm², the fractional bandwidth can be adjusted more effectively. The larger the overlap area S, the larger the area of the acoustic wave device 21. Therefore, it is preferred that the overlap area S is equal to or less than about 0.5×10⁵ μm², as described above. With such an arrangement, the fractional bandwidth can be effectively adjusted in a small area. Thus, it is possible to achieve miniaturization and adjust the fractional bandwidth.

As the wavelength λ, which is determined by the electrode finger pitch of the IDT electrode 6, changes, the inflection point at which the fractional bandwidth can be effectively reduced changes. For example, when λ becomes about ½, the overlap area S at the inflection point is about 0.25×10⁵ μm², which is about ½ of the above about 0.5×10⁵ μm². Therefore, it is preferred that the overlap area S is equal to or less than about λ×10⁴ μm². With such an arrangement, the fractional bandwidth can be effectively adjusted.

FIG. 6 is a schematic plan view explaining the positional relationship between an IDT electrode and a conductive material layer below the IDT electrode in an acoustic wave device 31 according to a variation of the second example embodiment. In the acoustic wave device 31, a conductive material layer 3 is not located below the intersecting region of an IDT electrode 6. More specifically, the conductive material layer 3 is located below a portion of a first busbar 11a and a second busbar 12a. A first portion 3a extending in the propagation direction of the acoustic wave is located below the first busbar 11a. A second portion 3b extending in the propagation direction of the acoustic wave is located below the second busbar 12a. The first portion 3a and the second portion 3b are connected, in the outer side portion of a second reflector 8, to a third portion 3c extending in a direction perpendicular or substantially perpendicular to the propagation direction of the acoustic wave.

Thus, the conductive material layer 3 in the present invention is not necessarily located below the intersecting region of the IDT electrode 6 or below the first and second reflectors 7 and 8. In this case as well, a capacitance can be generated between the first busbar 11a and the second busbar 12a. Therefore, as in the first and second example embodiments, the fractional bandwidth can be efficiently adjusted by forming the capacitance. Furthermore, in the acoustic wave device 31, electrical coupling and acoustic coupling are difficult to occur between the intersecting regions of the IDT electrode 6. Therefore, with such an arrangement, the acoustic wave device 31 can also obtain good characteristics.

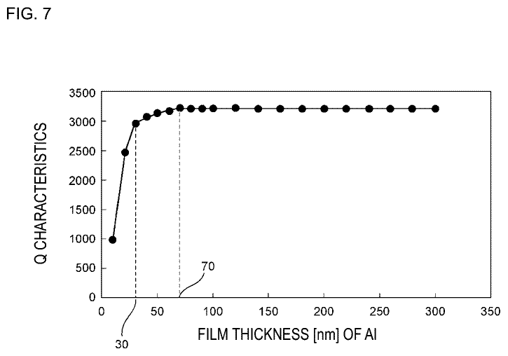

FIG. 7 is a graph showing the relationship between the film thickness [nm] of Al and the Q characteristics when the film thickness of the conductive material layer 3 in the second example embodiment of the acoustic wave device 21 is varied.

It is clear from FIG. 7 that as the film thickness of Al increases, the Q characteristics improve. It is preferred that the film thickness of Al is, for example, about 30 nm or more, so that the Q characteristics can be improved by reducing the resistance. It is more preferred that the film thickness of Al is, for example, about 70 nm or more. In such a case, the Q characteristics can be further improved, and furthermore, variations in the Q characteristics caused by variations in the film thickness of Al can be reduced or prevented.

Incidentally, the resistivity of Al was set to about 2.65×10⁻⁸ [Ω·m], for example. When the IDT electrode is made of other metal materials, it is preferred that the following Formula (2) be satisfied to thereby obtain equally good Q characteristics.

In other words, it is preferred that when the film thickness of the conductive material layer is represented as Tm [nm] and the area resistivity is represented as ρ [Ω·m], the following Formula (2) is satisfied.

Tm×(2.65×10⁻⁸))/ρ>30, i.e., Tm/ρ>1.13×10⁹ Formula (2)

When the film thickness of Al is about 70 nm or more, Tm/ρ>about 2.64×10⁹.

The material of the conductive material layer 3 is not limited to Al, but can be various metals and alloys. For example, among the various metals and alloys, Ti is preferred. When Ti is used, higher adhesive strength and better Q characteristics can be achieved. When Ti is used, it is preferred that the film thickness of Ti is at least about 10 nm but not more than about 50 nm, for example.

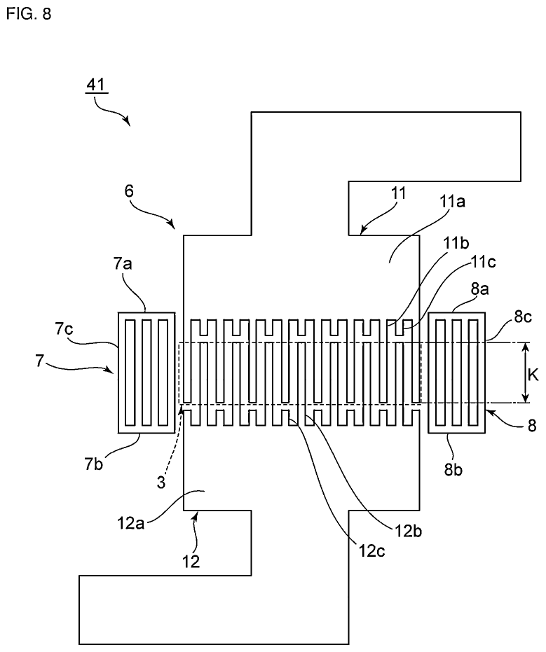

FIG. 8 is a schematic plan view illustrating the positional relationship between an IDT electrode and a conductive material layer below the IDT electrode in an acoustic wave device 41, which is a variation of the first example embodiment of the present invention. In the acoustic wave device 41, a conductive material layer 3 is located only below the intersecting region K of an IDT electrode 6. Thus, the conductive material layer 3 may be located only below the intersecting region K of the IDT electrode 6. In other words, the conductive material layer 3 is not necessarily present in positions overlapping a first reflector 7 and a second reflector 8 in plan view. Similarly, the conductive material layer 3 is not necessarily present in positions overlapping a first dummy electrode 11c and a second dummy electrode 12c in plan view. In other words, it is only required for the conductive material layer 3 to be present at least in the position overlapping the intersecting region K of the IDT electrode. However, the conductive material layer 3 preferably is arranged in the entire position overlapping the intersecting region K of the IDT electrode. In this case as well, the fractional bandwidth can be reduced by forming the conductive material layer 3.

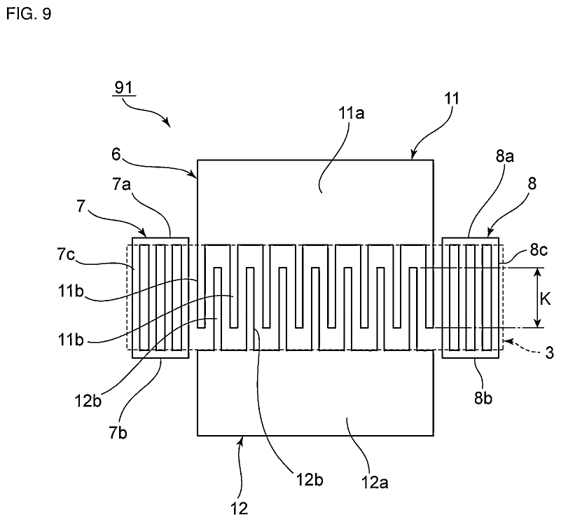

FIG. 9 is a schematic plan view explaining the positional relationship between an IDT electrode and a conductive material layer in an acoustic wave device according to a third example embodiment of the present invention. In an acoustic wave device 91 shown in FIG. 9, an IDT electrode 6 has no dummy electrode. Other configurations of the acoustic wave device 91 are preferably the same or substantially the same as those of the acoustic wave device 1. Thus, in the present invention, the dummy electrode is not necessarily provided. In this case as well, a high acoustic velocity region can be provided in the outer side portion of the intersecting region K to confine the surface acoustic wave. Thus, the characteristics can be improved. The conductive material layer 3 is not necessarily provided below the high acoustic velocity region. In this case, it is possible to achieve even higher acoustic velocity in the high acoustic velocity region. Thus, the confinement effect can be further improved.

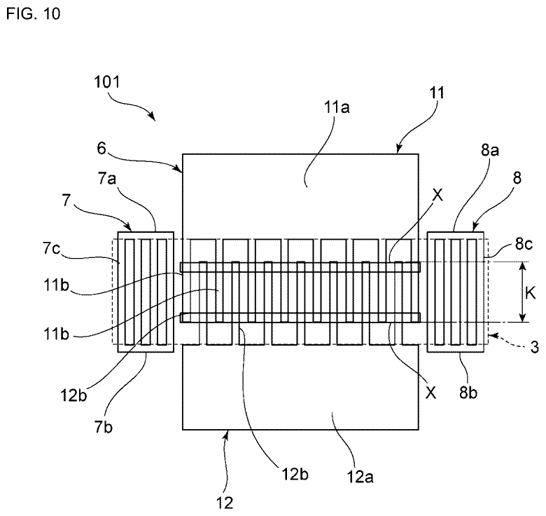

FIG. 10 is a schematic plan view explaining the positional relationship between an IDT electrode and a conductive material layer in an acoustic wave device according to a fourth example embodiment of the present invention. In an acoustic wave device 101 shown in FIG. 10, low acoustic velocity regions X and X are provided in the intersecting region K on both sides of the central region of first and second electrode fingers 11b and 12b in the extension direction of the electrode fingers. In the low acoustic velocity regions X and X, the acoustic velocity is lower than in the central region, and lower than in the high acoustic velocity region in the outer side portion. This allows the piston mode to be the desired mode, thereby reducing or preventing the transverse mode.

Such low acoustic velocity regions X and X can be provided by three-dimensionally stacking a mass-addition film on the first and second electrode fingers 11b and 12b. As another method of forming the low acoustic velocity regions X and X, an insulating material may be used to form the mass-addition film so as to extend beyond the adjacent first and second electrode fingers 11b and 12b in the propagation direction of the acoustic wave, as in the low acoustic velocity region X shown in the drawing. The mass-addition film may be provided only at the tip ends of the first and second electrode fingers 11b and 12b. In this case, the mass-addition film may be made of a metallic material.

In the acoustic wave device 101, the low acoustic velocity region X may be formed by making the width of the first and second electrode fingers 11b and 12b thicker than the central region. Alternatively, the width of the central region can be narrowed to provide the low acoustic velocity region X in the outer side portion of the central region.

In the above acoustic wave device 1, an example in which the piezoelectric layer is, for example, LiTaO₃ or LiNbO₃ was made to evaluate the temperature coefficient of frequency TCF.

The configuration of the example is as follows.

IDT electrode/LiNbO₃ or LiTaO₃/SiO₂ (thickness: about 0.125 μm)/Conductive material layer/SiO₂ (thickness: about 0.5 μm)/SiN (thickness: about 0.9 μm)/Silicon support substrate (111 plane), ψ=about 0°.

The IDT electrode was an Al film with a thickness of about 0.3 μm.

The conductive material layer was an Al film with a thickness of about 0.05 μm.

The wavelength λ of the IDT electrode was about 5.0 μm and the duty of the IDT electrode was about 0.45.

The cut-angle of LiNbO₃ or LiTaO₃ was about 50° Y/X propagation.

The conductive material layer was provided below the intersecting region of the IDT electrode and below the reflectors.

In such a configuration, the fractional bandwidth can be adjusted by providing a SiO₂ or SiN film as a dielectric layer between the conductive material layer and the support substrate.

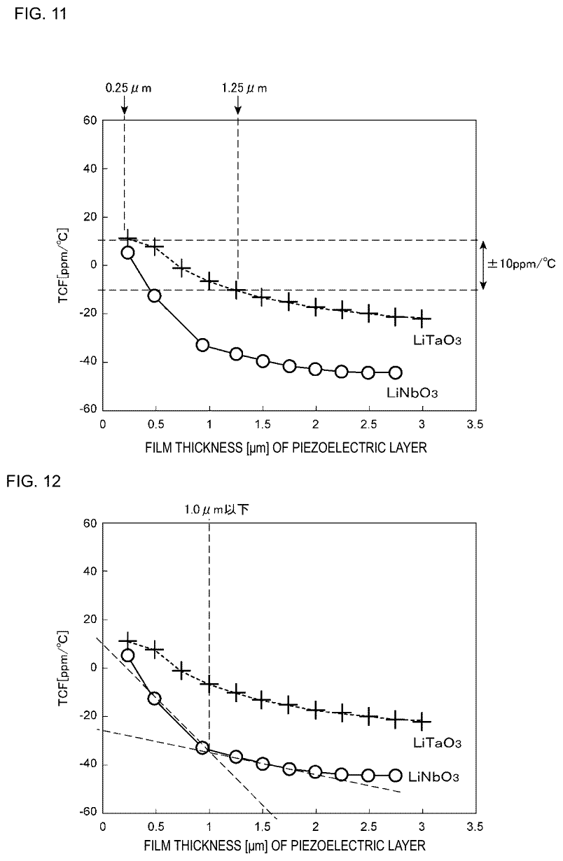

The relationship between the film thickness of the piezoelectric layer [μm] and the temperature coefficient of frequency TCF [ppm/° C.] when the film thickness of the piezoelectric layer is changed in the configuration of the above example is shown in FIG. 11.

When the piezoelectric layer is LiTaO₃, the temperature coefficient of frequency TCF can be within about ±10 ppm/° C. when the film thickness is set to about 0.25 μm or more and about 1.25 μm or less. In other words, for example, it is preferred that the film thickness is about 0.05λ or more and about 0.25λ or less when normalized to wavelength.

As in FIG. 11, FIG. 12 shows the relationship between the film thickness [μm] of the piezoelectric layer and the temperature coefficient of frequency TCF [ppm/° C.] in the above example. As shown in FIG. 12, when the piezoelectric layer is LiNbO₃, the inflection point exists at a position where the film thickness is 1 μm. For example, when the film thickness of LiNbO₃ is equal to or less than about 1 μm, i.e., equal to or less than about 0.20λ, the absolute value of the temperature coefficient of frequency TCF can be effectively reduced. Therefore, the film thickness of the LiNbO₃ is preferably equal to or less than about 0.20λ.

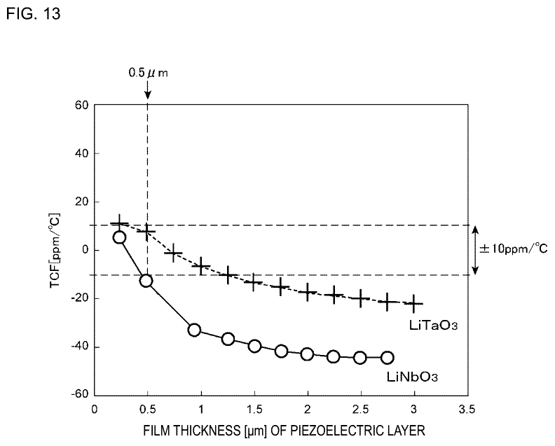

As in FIGS. 11 and 12, FIG. 13 shows the relationship between the film thickness [μm] of the piezoelectric layer and the temperature coefficient of frequency TCF [ppm/° C.]. It is clear from FIG. 13 that when the film thickness of LiNbO₃ is equal to or less than about 0.5 μm, i.e., equal to or less than about 0.1λ, the absolute value of the temperature coefficient of frequency TCF can be equal to or less than about 10 ppm/° C., which is more preferred.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface opposing each other;
an Interdigital Transducer (IDT) electrode on the first main surface of the piezoelectric layer;
a dielectric layer on the second main surface of the piezoelectric layer; and
a conductive material layer on a surface of the dielectric layer on a side opposite to the piezoelectric layer; wherein
the conductive material layer is provided in at least a portion of a region overlapping the IDT electrode in a plan view; and
when a film thickness of the piezoelectric layer is represented as Tp [λ] and a film thickness of the dielectric layer is represented as Td [λ], the Formula (1) is satisfied or Td=0, where λ is a wavelength determined by an electrode finger pitch of the IDT electrode, and Tp[λ]≥about 0.025:
Td[λ]≤−2.369×(Tp[λ])⁴
+2.721×(Tp[λ])³
−1.049×(Tp[λ])²
+0.076×(Tp[λ])
+0.095 Formula (1)

2. The acoustic wave device according to claim 1, wherein
the IDT electrode includes a first busbar, a second busbar, a plurality of first electrode fingers connected to the first busbar, and a plurality of second electrode fingers connected to the second busbar; and
the acoustic wave device further includes a first reflector and a second reflector on two sides in a propagation direction of an acoustic wave.

3. The acoustic wave device according to claim 2, wherein the conductive material layer is provided at a position overlapping, in the plan view, an intersecting region overlapping in the propagation direction of the acoustic wave.

4. The acoustic wave device according to claim 3, wherein the conductive material layer extends to a region adjacent to at least a portion of the first reflector and the second reflector in the plan view in addition to the intersecting region.

5. The acoustic wave device according to claim 3, wherein the first reflector and the second reflector are not connected to the IDT electrode.

6. The acoustic wave device according to claim 3, wherein the first reflector and the second reflector are connected to the IDT electrode.

7. The acoustic wave device according to claim 3, wherein the conductive material layer extends to a region overlapping at least a portion of the first busbar and the second busbar in the plan view.

8. An acoustic wave device comprising:
a piezoelectric layer including a first main surface and a second main surface opposing each other;
an Interdigital Transducer (IDT) electrode on the first main surface of the piezoelectric layer; and
a conductive material layer on a side of the second main surface of the piezoelectric layer; wherein
the IDT electrode includes first and second busbars, a plurality of first electrode fingers electrically connected to the first busbar, and a plurality of second electrode fingers electrically connected to the second busbar;
an area of the conductive material layer in a first overlapping region that overlaps at least a portion of the first busbar in a plan view is represented as an area S1;
an area of the conductive material layer in a second overlapping region that overlaps at least a portion of the second busbar in the plan view is represented as an area S2;
the first overlapping region and the second overlapping region of the conductive material layer are electrically connected, and a wavelength determined by an electrode finger pitch of the IDT electrode is represented as λ; and
a total area S, which represents a sum of the area S1 and the area S2, is equal to or less than about λ×10⁴ μm².

9. The acoustic wave device according to claim 8, further comprising a first reflector and a second reflector on two sides of the IDT electrode in a propagation direction of an acoustic wave.

10. The acoustic wave device according to claim 8, further comprising a dielectric layer between the second main surface of the piezoelectric layer and the conductive material layer.

11. The acoustic wave device according to claim 1, further comprising a support substrate stacked on a surface of the conductive material layer on a side opposite to the piezoelectric layer.

12. The acoustic wave device according to claim 1, wherein the dielectric layer is made of silicon oxide.

13. The acoustic wave device according to claim 11, further comprising a dielectric layer between the support substrate and the conductive material layer.

14. The acoustic wave device according to claim 1, wherein the piezoelectric layer is made of LiTaO₃ or LiNbO₃.

15. The acoustic wave device according to claim 1, wherein the piezoelectric layer is LiTaO₃ and a thickness thereof is about 0.05λ or more and about 0.25λ or less.

16. The acoustic wave device according to claim 1, wherein the piezoelectric layer is LiNbO₃ and a thickness thereof is equal to or less than about 0.2λ.

17. The acoustic wave device according to claim 1, wherein the piezoelectric layer is LiNbO₃ and a thickness thereof is equal to or less than about 0.1λ.

18. The acoustic wave device according to claim 1, wherein the conductive material layer is made of metal.

19. The acoustic wave device according to claim 1, wherein the conductive material layer is a floating electrode.

20. The acoustic wave device according to claim 1, wherein
the IDT electrode includes a first busbar, a second busbar, a plurality of first electrode fingers connected to the first busbar, and a plurality of second electrode fingers connected to the second busbar; and
the IDT electrode includes an intersecting region where the first and second electrode fingers overlap in a propagation direction of an acoustic wave, and the intersecting region includes a central region and a low acoustic velocity region located on both sides of the central region in a direction in which the first and second electrode fingers extend, and a high acoustic velocity region is provided in an outer side portion of the low acoustic velocity region.
